(19) United States
(12) Patent Application Publication
(10) Pub. No.: US 2013/0307064 A1
(43) Pub. Date: Nov. 21, 2013

(54) POWER TRANSISTOR DEVICE AND FABRICATING METHOD THEREOF

(71) Applicant: Anpec Electronics Corporation, Hsin-Chu (TW)

(72) Inventors: Yung-Fa Lin, Hsinchu City (TW); Shou-Yi Hsu, Hsinchu County (TW); Meng-Wei Wu, Hsinchu City (TW); Chia-Hao Chang, Hsinchu City (TW)

(73) Assignee: Anpec Electronics Corporation, Hsin-Chu (TW)

(21) Appl. No.: 13/957,444

(22) Filed: Aug. 2, 2013

Related U.S. Application Data
(62) Division of application No. 13/451,557, filed on Apr. 20, 2012.

(30) Foreign Application Priority Data
Aug. 19, 2011 (TW) 100129831

(51) Int. Cl. H01L 29/78; H01L 29/66

(52) U.S. Cl. CPC H01L 29/7827; H01L 29/66666
USPC 257/330; 438/270

(57) ABSTRACT

The present invention provides a power transistor device including a substrate, a first epitaxial layer, a doped diffusion region, a second epitaxial layer, a doped base region, and a doped source region. The substrate, the first epitaxial layer, the second epitaxial layer and the doped source region have a first conductive type, and the doped diffusion region and the doped base region have a second conductive type. The first epitaxial layer and the second epitaxial layer are sequentially disposed on the substrate, and the doped diffusion region is disposed in the first epitaxial layer. The doped base region is disposed in the second epitaxial layer and contacts the doped diffusion region, and the doped source region is disposed in the doped base region. A doping concentration of the second epitaxial layer is less than a doping concentration of the first epitaxial layer.

### CROSS REFERENCE TO RELATED APPLICATIONS

This application is a divisional application of and claims the benefit of U.S. patent application Ser. No. 13/451,557, filed Apr. 20, 2012.

### BACKGROUND OF THE INVENTION

1. Field of the Invention

The present invention relates to a power transistor device and a method of fabricating the same, and, particularly, to a power transistor device having a super junction and a method of fabricating the same.

2. Description of the Prior Art

In a power transistor device, power consumption is directly proportional to on-resistance (RDS (on)) between drain and source of the device, and thus the power consumption of the power transistor device can be reduced by decreasing the on-resistance. Resistance generated from an epitaxial layer used for bearing voltage occupies the largest percentage of the on-resistance. The resistance of the epitaxial layer can be decreased by increasing the doping concentration of the dopant; however, the epitaxial layer is used to tolerate high voltage, and the breakdown voltage of the epitaxial layer is reduced when the doping concentration is increased, so that ability to tolerate the voltage of power transistor device is reduced. For this reason, a power transistor device having a super junction structure is developed to have both high voltage bearing ability and low on-resistance.

Refer to FIG. 1, which is a schematic diagram illustrating a cross-sectional view of a conventional power transistor device having a super junction structure. As shown in FIG. 1, the power transistor device 10 includes an n-type substrate 12, an n-type epitaxial layer 14, a plurality of p-type epitaxial layers 16, a plurality of p-type doped base regions 18, a plurality of n-type doped source regions 20, a plurality of gate structures 22 each including a gate 22a, a gate oxide layer 22b beneath the gate 22a, and a gate insulation layer 22c around the gate 22a, a source metal layer 24 and a drain metal layer 26. The n-type epitaxial layer 14 has a plurality of deep trenches 28, and each p-type epitaxial layer 16 is respectively filled into each deep trench 28, so that the n-type epitaxial layer 14 and each p-type epitaxial layer 16 are disposed alternatively in sequence along a horizontal direction. In addition, each p-type doped base region 18 is disposed on each p-type epitaxial layer 16, and each n-type doped source region 20 is respectively disposed in each p-type doped base region 18. Each gate structure 22 is respectively disposed on the n-type epitaxial layer 14 between the adjacent p-type doped base regions 18. The source metal layer 24 is formed on the upper surface of the n-type epitaxial layer 14, connects with the n-type doped source regions 20 and the p-type doped base regions 18, and is electrically connected to the p-type epitaxial layer 16. The drain metal layer 26 is formed on the back side of the n-type substrate 12, connects with the n-type substrate 12, and is electrically connected to the n-type epitaxial layer 14. The junction formed by the n-type epitaxial layer 14 and the p-type epitaxial layer 16 is a super junction.

The tolerable voltage of a conventional power transistor device without a super junction structure depends on the vertical electric field generated by the p-type doped base region and the n-type epitaxial layer. While, the tolerable voltage of a power transistor device with a super junction structure is improved through an additional lateral electric field generated by the super junction. Accordingly, with respect to a power transistor device with a super junction structure, it is unnecessary to reduce the doping concentration of the n-type epitaxial layer, which leads increase of on-resistance, for increasing the tolerable voltage. Thus, in a power transistor device with a super junction structure, on-resistance can be reduced by increasing the doping concentration of the n-type epitaxial layer and at the same time a high breakdown voltage can be maintained. However, although increasing the doping concentration of the n-type epitaxial layer may reduce the on-resistance of the power transistor device, the required concentration of p-type dopant is increased to alter the conductivity type for forming p-type doped base regions within an n-type epitaxial layer. Thereby, the concentration of the p-type doped base regions thus formed is not easily controlled and too high to give a stable channel region of the power transistor device, leading to an uneasily-controlled threshold voltage for the power transistor device.

For these reasons, to stably control the threshold voltage of a power transistor device while maintaining high voltage bearing ability and low on-resistance is an important objective.

### SUMMARY OF THE INVENTION

One of main objectives of the present invention is to provide a power transistor device and a method of fabricating the same, for stably controlling and reducing threshold voltage of power transistor device while maintaining high voltage bearing ability and low on-resistance.

For the aforesaid objective, a power transistor device according to one embodiment of the present invention is provided. The power transistor device includes a substrate, a first epitaxial layer, a doped diffusion region, a second epitaxial layer, a doped base region, a doped source region, and a gate structure. The substrate has a first conductive type. The first epitaxial layer is disposed on the substrate and has the first conductive type. The first epitaxial layer has a first doping concentration. The doped diffusion region is disposed in the first epitaxial layer and has a second conductive type different from the first conductive type. The second epitaxial layer is disposed on the first epitaxial layer and the doped diffusion region and has the first conductive type. The second epitaxial layer has a second doping concentration. The second doping concentration is less than the first doping concentration. The doped base region is disposed in the second epitaxial layer and contacts the doped diffusion region. The doped base region has the second conductive type. The doped source region is disposed in the doped base region and has the first conductive type. The gate structure is disposed on the doped base region between the second epitaxial layer and the doped source region.

For the aforesaid objective, a power transistor device according to another embodiment of the present invention is provided. The power transistor device includes a substrate, a first epitaxial layer, a doped diffusion region, a second epitaxial layer, a gate structure, and a doped source region. The substrate has a first conductive type. The first epitaxial layer is disposed on the substrate and has a second conductive type different from the first conductive type. The first epitaxial layer has a first resistivity. The doped diffusion region is disposed in the first epitaxial layer and has the first conductive type. The second epitaxial layer is disposed on the first epitaxial layer and the doped diffusion region and has the second conductive type. The second epitaxial layer has at least one through hole. The second epitaxial layer has a second resistivity. The second resistivity is greater than the first resistivity. The gate structure is disposed in the through hole. The doped source region is disposed in the second epitaxial layer at one side of the through hole, and the doped source region has the first conductive type.

For the aforesaid objective, a method of fabricating a power transistor device according to further another embodiment of the present invention is provided. The method includes steps as follows. First, a substrate is provided. The substrate has a first conductive type. Thereafter, a first epitaxial layer is formed on the substrate and has the first conductive type. The first epitaxial layer has a first doping concentration. Thereafter, a second epitaxial layer is formed on the first epitaxial layer and has the first conductive type. The second epitaxial layer has a second doping concentration. The second doping concentration is less than the first doping concentration. Thereafter, a doped diffusion region is formed in the first epitaxial layer. The doped diffusion region has a second conductive type different from the first conductive type. Thereafter, a gate structure is formed on the second epitaxial layer. Thereafter, a doped base region is formed in the second epitaxial layer. The doped base region contacts the doped diffusion region and has the second conductive type. Thereafter, a doped source region is formed in the doped base region and has the first conductive type.

For the aforesaid objective, a method of fabricating a power transistor device according to still another embodiment of the present invention is provided. The method includes steps as follows. First, a substrate is provided. The substrate has a first conductive type. Thereafter, a first epitaxial layer is formed on the substrate. The first epitaxial layer has a second conductive type different from the first conductive type. The first epitaxial layer has a first resistivity. Thereafter, a second epitaxial layer is formed on the first epitaxial layer and has the second conductive type. The second epitaxial layer has at least one through hole and has a second resistivity. The second resistivity is greater than the first resistivity. Thereafter, a doped diffusion region is formed in the first epitaxial layer and has the first conductive type. Thereafter, a gate structure is formed in the through hole. Thereafter, a doped source region is formed in the second epitaxial layer at one side of the through hole. The doped source region has the first conductive type.

Summarized from the above description, in the present invention, the doping concentration of the second epitaxial layer on the first epitaxial layer is made to be less than the doping concentration of the first epitaxial layer, so that the concentration of dopant further required in the step of forming a doped base region in the second epitaxial layer can be reduced, and, in turn, the doping concentration of channel region of the power transistor device can be stably controlled. Thereby, the threshold voltage of the power transistor device can be reduced and effectively controlled. Furthermore, in the case that the second epitaxial layer is employed to serve as the drain of the power transistor device, since the thickness of the first epitaxial layer is greater than the thickness of the second epitaxial layer, making the second doping concentration less than the first doping concentration lead to that the first resistivity of the first epitaxial layer is lower than the second resistivity of the second epitaxial layer, and the on-resistance of the power transistor device may be further reduced.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic cross-sectional view illustrating a conventional power transistor device having a super junction structure;

FIGS. 2 to 8 are schematic cross-sectional views illustrating a method of fabricating a power transistor device according to a first preferred embodiment of the present invention;

FIGS. 9 to 13 are schematic cross-sectional views illustrating a method of fabricating a power transistor device according to a second preferred embodiment of the present invention;

FIGS. 14 to 19 are schematic cross-sectional views illustrating a method of fabricating a power transistor device according to a third preferred embodiment of the present invention; and

FIGS. 20 to 21 are schematic cross-sectional views illustrating a method of fabricating a power transistor device according to a fourth preferred embodiment of the present invention.

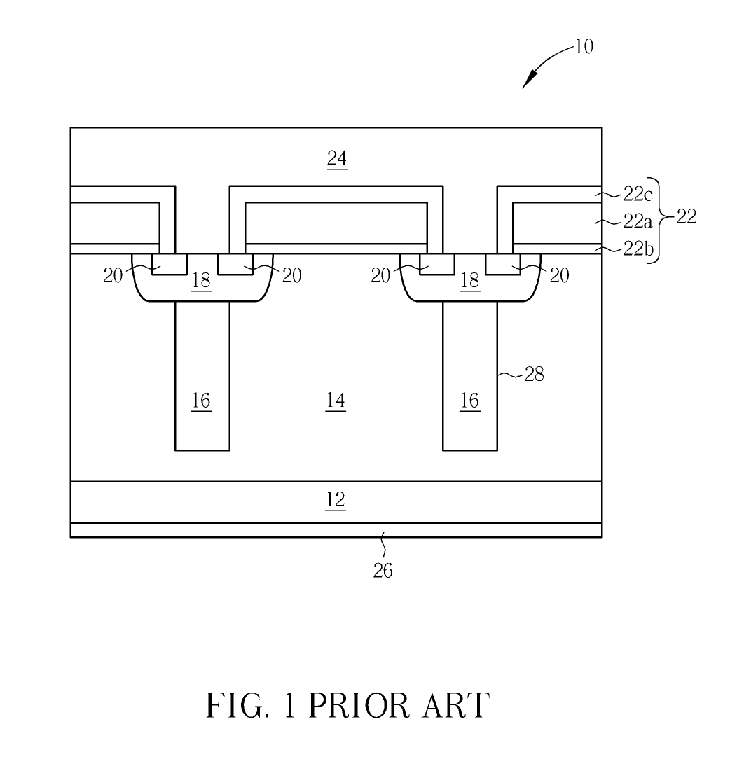

### DETAILED DESCRIPTION

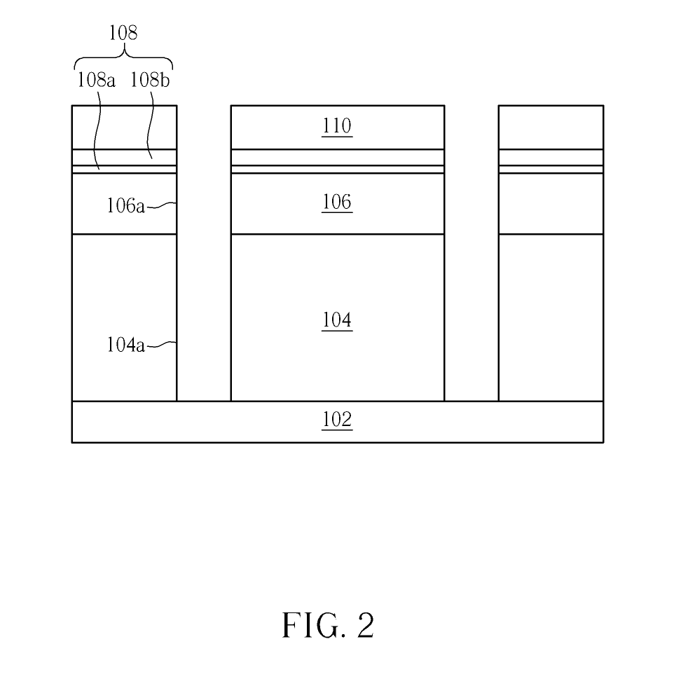

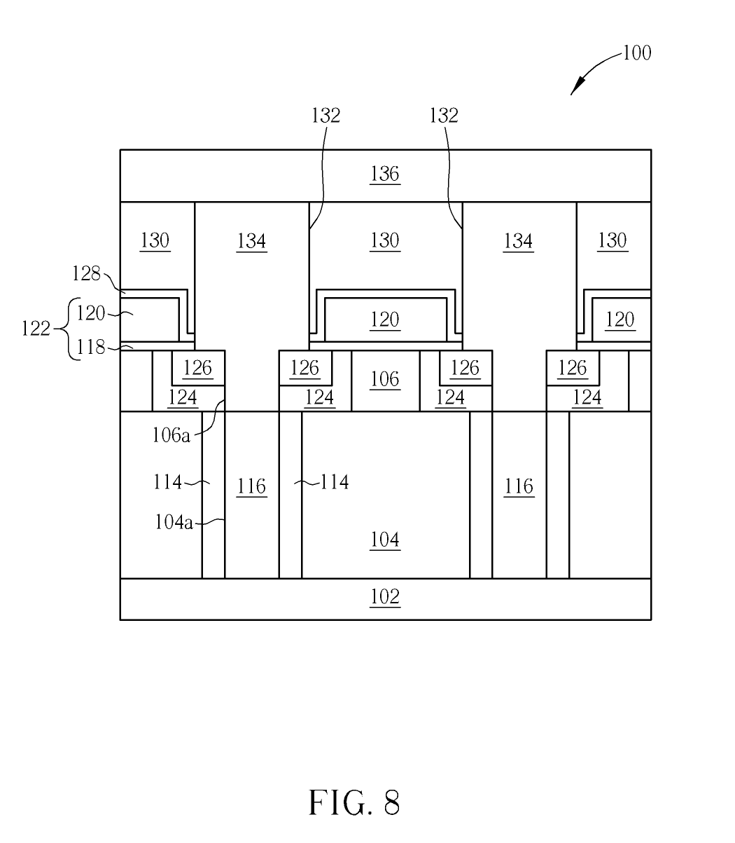

Please refer to FIGS. 2 to 8. FIGS. 2 to 8 are schematic cross-sectional views illustrating a method of fabricating a power transistor device according to a first preferred embodiment of the present invention. FIG. 8 is a schematic cross-sectional view illustrating a power transistor device according to the first preferred embodiment of the present invention. As shown in FIG. 2, first, a substrate 102 is provided. The substrate 102 has a first conductive type. Thereafter, a first epitaxial layer 104 having a first doping concentration and a second epitaxial layer 106 having a second doping concentration are sequentially formed on the substrate 102. The first epitaxial layer 104 and the second epitaxial layer 106 have the first conductive type. Thereafter, a pad layer 108 is formed on the second epitaxial layer 106. The pad layer 108 may include two portions, an upper pad layer 108b and a lower pad layer 108a. The upper pad layer 108b may include material such as silicon nitride (Si₃N₄). The lower pad layer 108a may include material such as silicon dioxide (SiO₂). Thereafter, a hard mask layer 110, such as silicon oxide layer, is formed on the surface of the pad layer 108 by a deposition process. Thereafter, photolithography and etch processes are carried out to pattern the hard mask layer 110 and pad layer 108 to expose the second epitaxial layer 106. Thereafter, a plurality of through holes 106a are formed in the second epitaxial layer 106, and the etch is continuously performed on the first epitaxial layer 104 to form a plurality of trenches 104a in the first epitaxial layer 104. Each trench 104a is exposed from a through hole 106a. In this embodiment, the substrate 102 may be a silicon substrate or a silicon wafer, which may serve for forming a drain of a power transistor device, and the first conductive type is n type, but not limited thereto. Furthermore, the n-type first epitaxial layer 104 has a first resistivity, and the n-type second epitaxial layer 106 has a second resistivity. In this embodiment, the second doping concentration of the n-type second epitaxial layer 106 is less than the first doping concentration of the n-type first epitaxial layer 104, such that the second resistivity is greater than the first resistivity. In this embodiment, it is preferred that the first doping concentration is greater than two times the second doping concentration, but not limited thereto. Moreover, the thickness of the n-type second epitaxial layer 106 is less than the thickness of the n-type first epitaxial layer 104. The thickness of the n-type second epitaxial layer 106 of this embodiment is preferably greater than one micrometer, but not limited thereto, such that the subsequently-formed doped base region can be formed therein. The thickness of the n-type first epitaxial layer 104 of this embodiment is preferably greater than 5 micrometers in order to maintain the voltage bearing ability of the power transistor device. In addition, the n-type first epitaxial layer 104 and the n-type second epitaxial layer 106 may be formed using an epitaxial growth process by introducing n-type dopant of different concentrations at different times, or using two epitaxial growth processes sequentially, but the present invention is not limited thereto. In addition, each trench 104a in the present invention is not limited to passing through the n-type first epitaxial layer 104, i.e. it may not fully pass through the n-type first epitaxial layer 104, or it may pass through the n-type first epitaxial layer 104 and extend into the n-type substrate 102. There may be one or a plurality of trenches 104a.

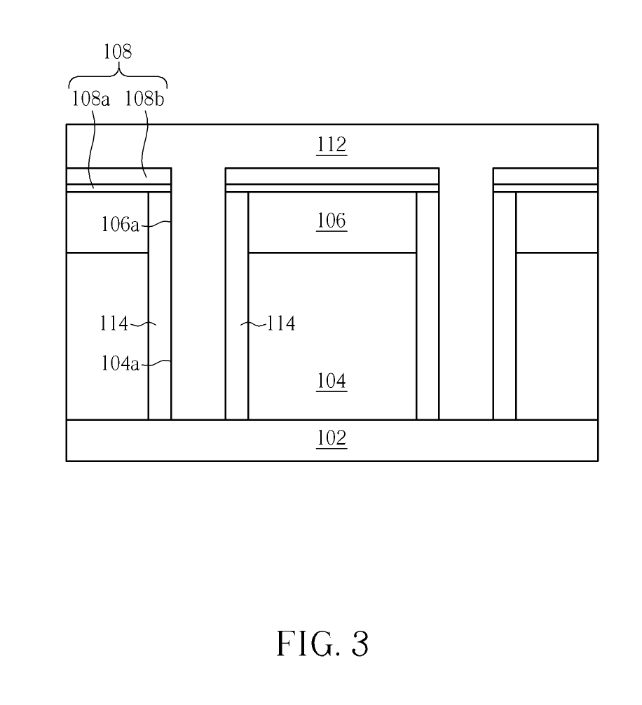

As shown in FIG. 3, the hard mask layer 110 is subsequently removed, and each trench 104a is filled with a dopant source layer 112. The dopant source layer 112 includes a dopant of the second conductive type. Thereafter, a thermal drive-in process is carried out to diffuse the dopants into the n-type first epitaxial layer 104 and the n-type second epitaxial layer 106 to form two doped diffusion region 114 in the n-type first epitaxial layer 104 at two sides of each trench 104a and in the n-type second epitaxial layer 106 at two sides of each through hole 106a, respectively. The doped diffusion region 114 has a second conductive type. In this embodiment, the second conductive type is p type, and the p-type doped diffusion region 114 is formed by uniform diffusion of p-type dopants from the sidewalls of each trench 104a and each through hole 106a into the n-type first epitaxial layer 104, allowing a PN junction, i.e. super junction, to be formed between the p-type doped diffusion region 114 and the n-type first epitaxial layer 104. The PN junction is approximately perpendicular to the n-type substrate 102. The first conductive type and the second conductive type according to the present invention are not limited to the n- and p-types described above respectively, and they are interchangeable with each other. Furthermore, the material for forming the dopant source layer 112 may include boron silicate glass (BSG), but be not limited thereto. In other embodiments of the present invention, before the dopant source layer 112 is formed, a buffer layer, such as a silicon oxide layer, may be formed in each trench 104a in advance, and, thereafter, the dopant source layer 112 is formed and the p-type dopants are allowed to diffuse into the n-type first epitaxial layer 104, so as to favor a uniform diffusion of the p-type dopants into the n-type first epitaxial layer 104 to form a smooth PN junction.

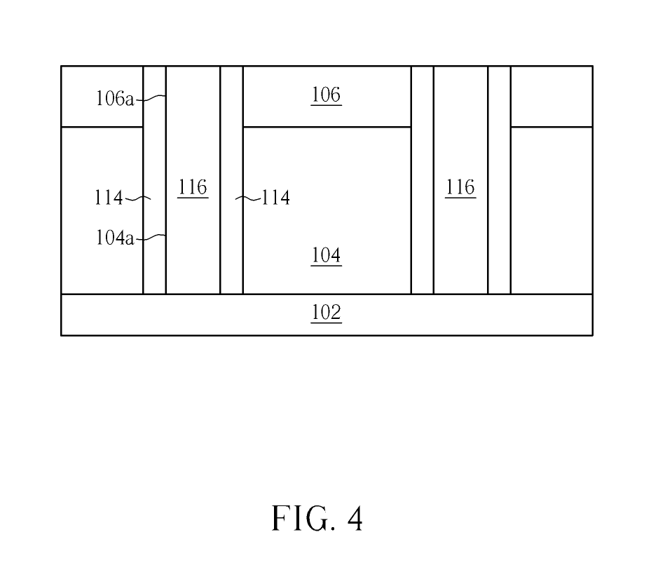

Thereafter, as shown in FIG. 4, the dopant source layer 112 is removed to expose the upper surface of the pad layer 108 and the sidewalls of each through hole 106a and each trench 104a. Thereafter, an insulation layer 116 is formed all over on the surface of the pad layer 108 and filled into each trench 104a. Thereafter, a chemical-mechanical polishing process and an etch-back process are carried out to allow the upper surface of the insulation layer 116 and the n-type second epitaxial layer 106 to be at a same height level. Thereafter, the pad layer 108 is removed to expose the upper surface of the n-type second epitaxial layer 106.

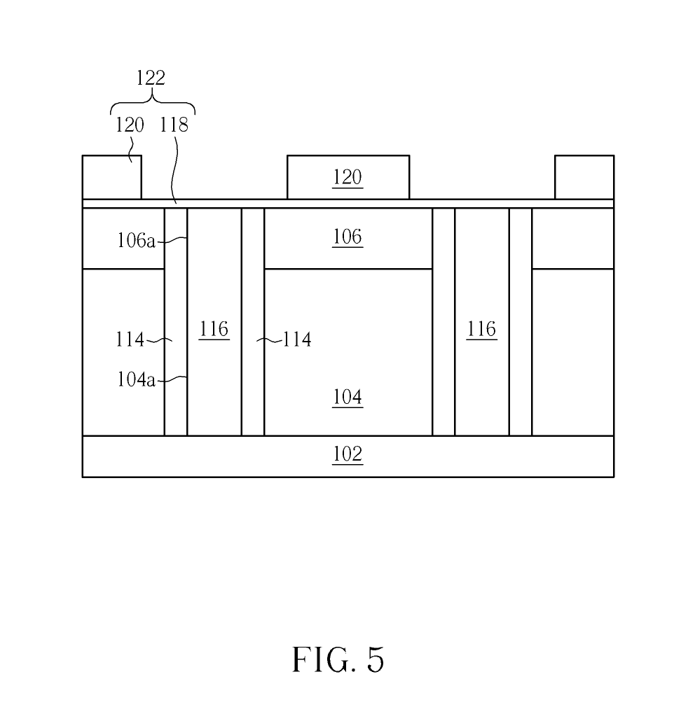

Thereafter, as shown in FIG. 5, a gate insulation layer 118 is formed on the n-type second epitaxial layer 106 and a conductive layer is formed on the gate insulation layer 118. Thereafter, the conductive layer is patterned to form a plurality of gate conductive layers 120. Each gate conductive layer 120 and the gate insulation layer 118 form a gate structure 122. In this embodiment, the gate conductive layer 120 is the gate of a power transistor device and may include doped polysilicon, but be not limited thereto.

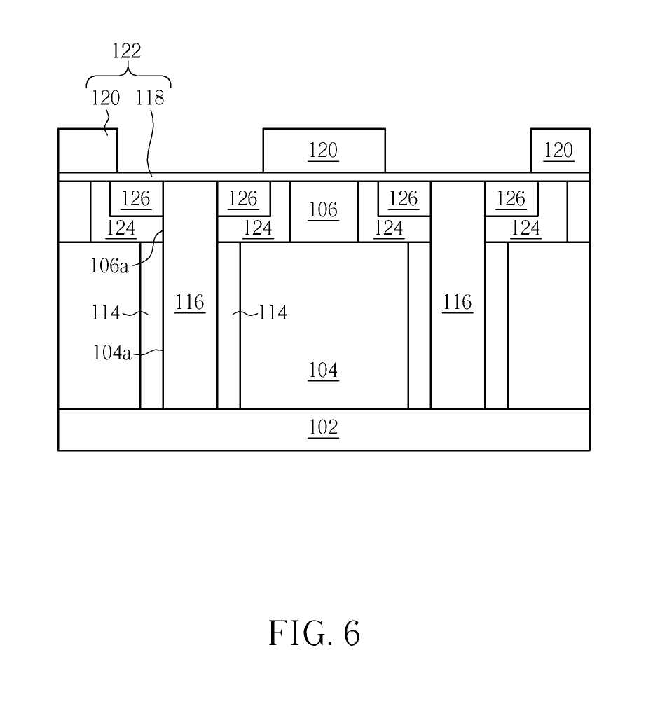

Thereafter, as shown in FIG. 6, a p-type ion implantation process and a thermal drive-in process are carried out to form two p-type doped base regions 124 in the n-type second epitaxial layer 106 at two sides of each through hole 106a, respectively, for serving as a base of a power transistor device. One portion of each p-type doped base region 124 is formed in each p-type doped diffusion region 114 at the same side of each through hole 106a, and both contact each other. Thereafter, an n-type ion implantation process and a thermal drive-in process are carried out to form an n-type doped source region 126 in the p-type doped base region 124, for serving as a source of a power transistor device. The gate structure 122 is on the p-type doped base region 124 between the n-type second epitaxial layer 106 and the n-type doped source region 126, and the n-type second epitaxial layer 106 serves as a drain of a power transistor device. For these reasons, the power transistor device according to this embodiment is a planar power transistor device. The p-type doped base region 124 in the present invention is not limited to being disposed only within the n-type second epitaxial layer 106 only, but it may extend into the n-type first epitaxial layer 104.

It may be noted that, if the second doping concentration of the n-type second epitaxial layer 106 is high, it will require increasing the concentration of the p-type dopant incorporated in the step of forming the p-type doped base region 124 in order to obtain a p-type doped base region 124 having a desired doping concentration, resulting in difficult control of the concentration of the obtained p-type doped base region 124. Accordingly, in this embodiment, by adjusting the second doping concentration of the n-type second epitaxial layer 106 to be less than the first doping concentration of the n-type first epitaxial layer 104, the concentration of the p-type dopant incorporated into the n-type second epitaxial layer 106 for forming the p-type doped base region 124 can be reduced, and in turn the doping concentration of the obtained p-type doped base region 124 can be effectively controlled, i.e. the doping concentration in the channel region of the power transistor device can be stably controlled, which leads to an effective control of the threshold voltage of the power transistor device. Furthermore, since the thickness of the n-type first epitaxial layer is greater than the thickness of the n-type second epitaxial layer, the on-resistance of the power transistor device can be reduced through the adjustment of the second doping concentration being less than the first doping concentration to allow the first resistivity of the n-type first epitaxial layer 104 to be less than the second resistivity of the n-type second epitaxial layer 106.

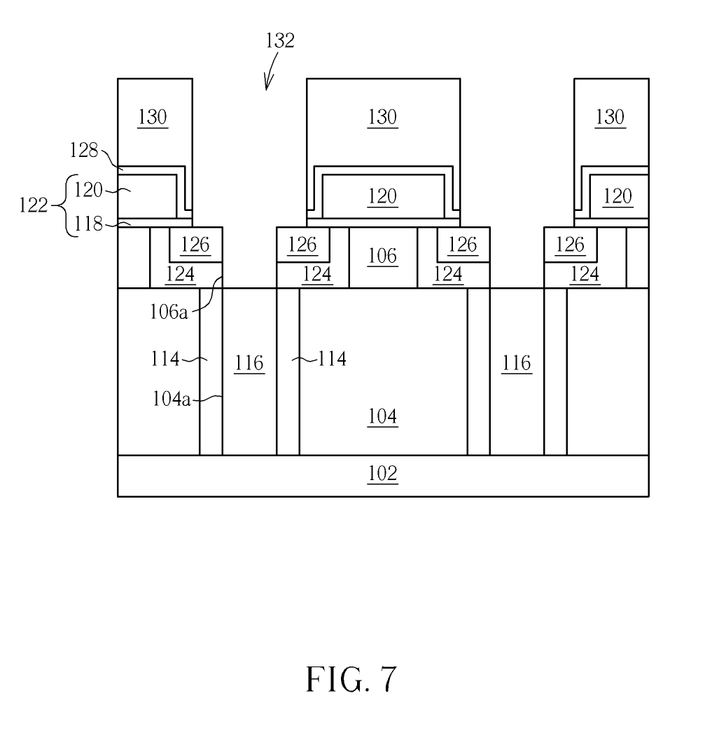

Thereafter, as shown in FIG. 7, a lining layer 128 and a dielectric layer 130 are formed in sequence to cover the gate conductive layer 120 and the gate insulation layer 118. Thereafter, the lining layer 128, the dielectric layer 130 and the gate insulation layer 118 above all the trenches 104a are patterned, and the portion of the insulation layer 116 within each through hole 106a is removed, to forma contact hole 132 above each trench 104a, so that the contact holes 132 expose the insulation layer 116 within each trench 104a. Besides, with the patterning, a contact hole 132 (not shown) may be also formed on the gate conductive layer 120 to serve as a gate contact hole. In other embodiments of the present invention, a p-type ion implantation process and a thermal drive-in process may be carried out after formation of the contact holes 132 to form a p-type doped contact region in each p-type doped base region 124, but not limited thereto.

Thereafter, as shown in FIG. 8, a contact plug 134 is formed within each contact hole 132 above the insulation layer 116. The contact plug 134 contacts both of the n-type doped source region 126 and the p-type doped base region 124. Thereafter, a source metal layer 136 is formed on the dielectric layer 130 and the contact plug 134. The source metal layer 136 is electrically connected to the n-type doped source region 126 and the p-type doped base region 124 through the contact plug 134, so that they have an identical electrical potential. Furthermore, a gate wiring and a source wiring may be formed through photolithography and etching processes. Furthermore, a drain metal layer may be formed on the back of the n-type substrate 102 for forming a drain wiring. A power transistor device 100 according to this embodiment is accordingly formed. Material for forming the contact plugs 134 may include metal material, such as tungsten or copper. Material for forming the source metal layer 136, gate wiring, source wiring, drain metal layer or drain wiring may include metal material, such as titanium or aluminum.

For the above reasons, in the power transistor device 100 according to the present invention, the threshold voltage of the power transistor device can be stably controlled and effectively reduced by allowing the second doping concentration of the n-type second epitaxial layer 106 to be less than the first doping concentration of the n-type first epitaxial layer 104.

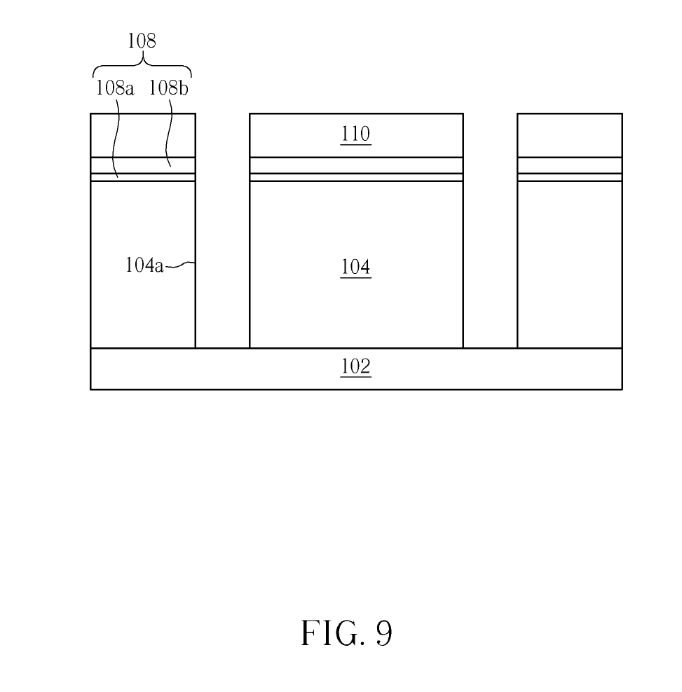

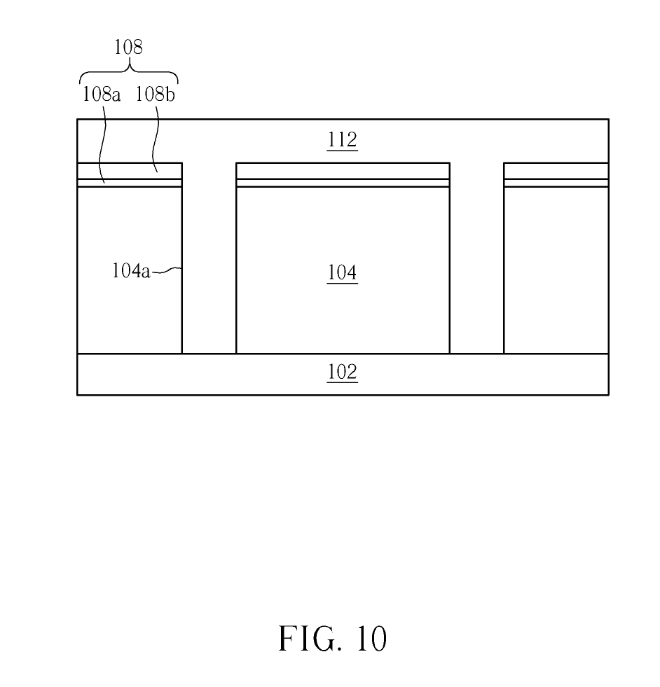

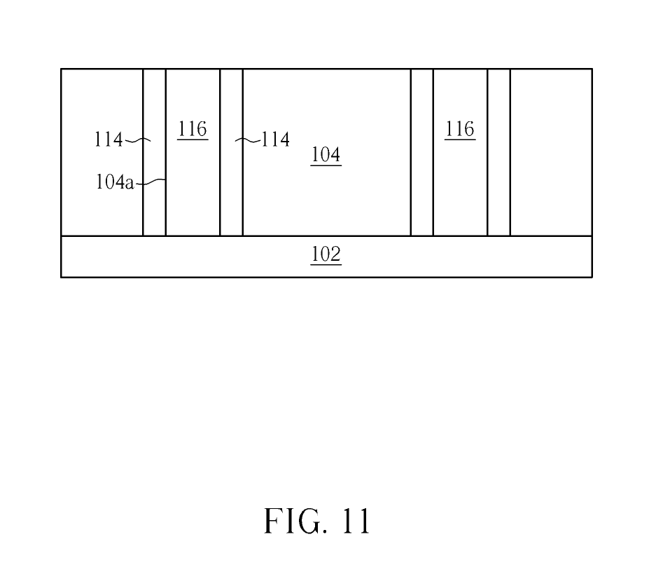

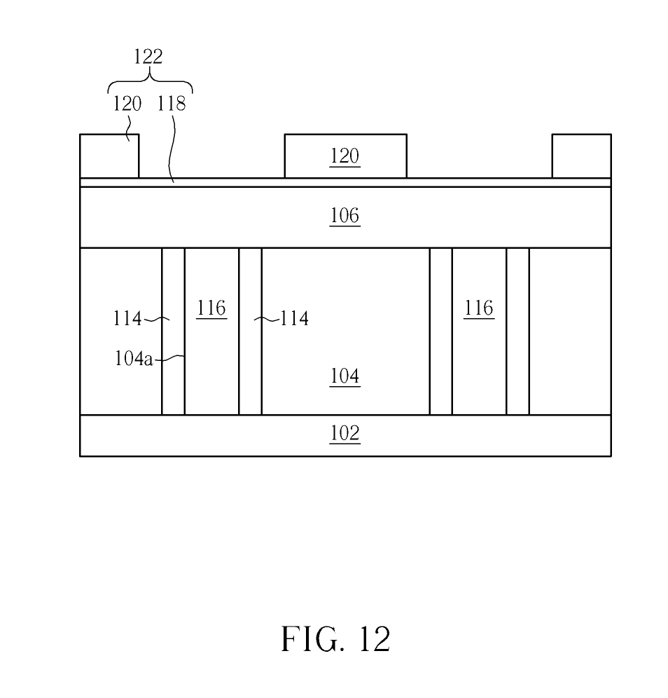

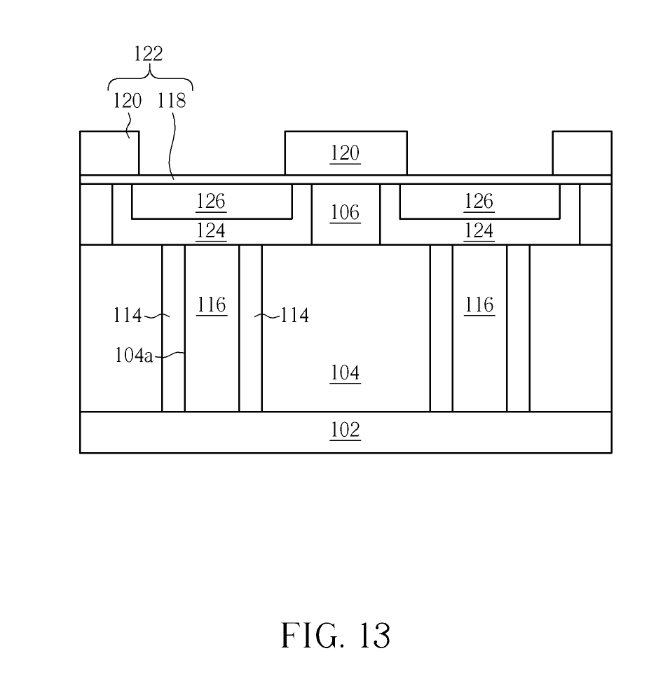

The method of fabricating a power transistor device according to the present invention is not limited to forming the n-type first epitaxial layer and the n-type second epitaxial layer in advance and thereafter forming the p-type doped diffusion region. The step of forming the p-type doped diffusion region may be carried out between the step of forming the n-type first epitaxial layer and the step of forming the n-type second epitaxial layer. Please refer to FIGS. 9 to 13 with FIGS. 7 and 8 together. FIGS. 9 to 13 are schematic cross-sectional views illustrating a method of fabricating a power transistor device according to a second preferred embodiment of the present invention. Some elements the same as those in the first embodiment may be denoted with the same referral numbers and some steps the same as those in the first embodiment may be not redundantly described for conciseness. As shown in FIG. 9, in comparison with the method according to the first embodiment, in the method according to the second embodiment, the pad layer 108 and the hard mask layer 110 are formed on the n-type first epitaxial layer 104 after the n-type first epitaxial layer 104 is formed. Thereafter, photolithography and etch processes are carried out to pattern the hard mask layer 110 and pad layer 108 to expose the n-type first epitaxial layer 104. Thereafter, the trenches 104a are formed in the n-type first epitaxial layer 104. As shown in FIG. 10, the hard mask layer 110 is subsequently removed, and each trench 104a is filled with a dopant source layer 112. Thereafter, a thermal drive-in process is carried out to diffuse P-type dopants into the n-type first epitaxial layer 104 to form two p-type doped diffusion regions 114 in the n-type first epitaxial layer 104 at two sides of each trench 104a. Thereafter, as shown in FIG. 11, the dopant source layer 112 is removed to expose the upper surface of the pad layer 108 and the sidewalls of each trench 104a. Thereafter, an insulation layer 116 is formed all over on the surface of the pad layer 108, and it allows each trench 104a to be filled with the insulation layer 116. Thereafter, the pad layer 108 and the insulation layer 116 located outside each trench 104a are removed. Thereafter, as shown in FIG. 12, an n-type second epitaxial layer 106, a gate insulation layer 118 and a conductive layer are formed in sequence on the n-type first epitaxial layer 104 and the insulation layer 116. Thereafter, the conductive layer is patterned to form the gate conductive layers 120. Thereafter, as shown in FIG. 13, a p-type ion implantation process and a thermal drive-in process are carried out to form the p-type doped base regions 124 in the n-type second epitaxial layer 106 to contact the p-type doped diffusion region 114. Thereafter, an n-type ion implantation process and a thermal drive-in process are carried out to form the n-type doped source region 126 in the p-type doped base region 124. Thereafter, as shown in FIG. 7, a lining layer 128 and a dielectric layer 130 are formed in sequence to cover the gate conductive layer 120 and the gate insulation layer 118. Thereafter, the lining layer 128, the dielectric layer 130 and the gate insulation layer 118 above all the trenches 104a are patterned, and the through holes 106a are formed in the n-type second epitaxial layer 106, to form a contact hole 132 in the lining layer 128, the dielectric layer 130, the gate insulation layer 118 and the n-type second epitaxial layer 106 above each trench 104a. The contact holes 132 expose the insulation layer 116 within each trench 104a. Since the step of forming the contact plugs 134 and the following steps in this embodiment are the same as those described in the first embodiment, and the obtained power transistor device 100 also has a structure the same as that described in the first embodiment, as shown in FIG. 8, they are not described redundantly herein for conciseness.

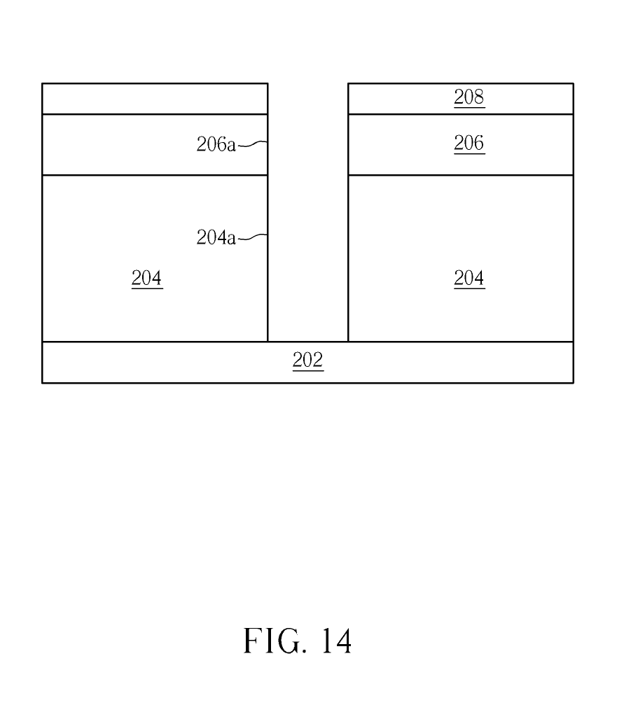

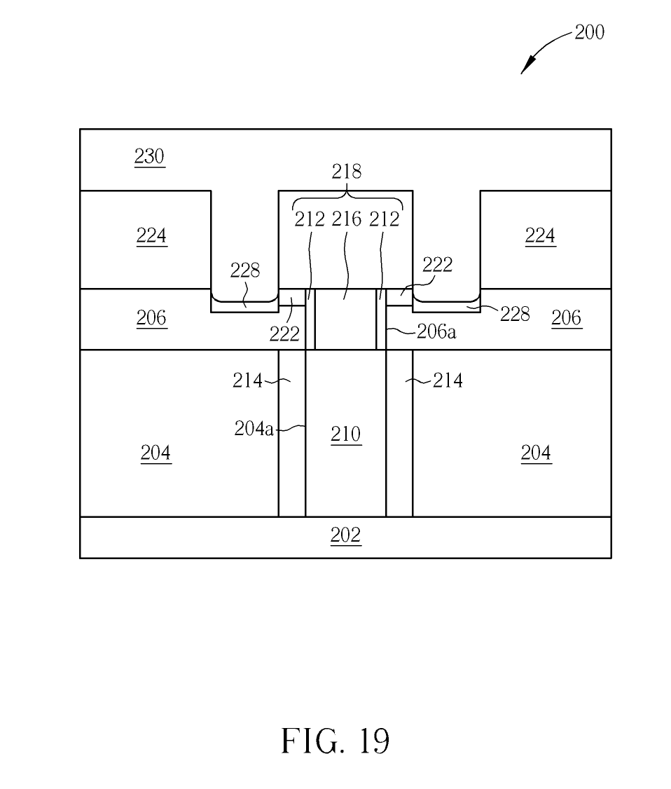

Furthermore, the power transistor device according to the present invention is not limited to a planar power transistor device but may be a trench-type power transistor device. FIGS. 14 to 19 are schematic cross-sectional views illustrating a method of fabricating a power transistor device according to a third preferred embodiment of the present invention. FIG. 19 is a schematic cross-sectional view illustrating a power transistor device according to the third preferred embodiment of the present invention. As shown in FIG. 14, first, an n-type substrate 202 is provided. Thereafter, a p-type first epitaxial layer 204 and a p-type second epitaxial layer 206 are formed in sequence on the n-type substrate 202. The first doping concentration of the p-type first epitaxial layer 204 is greater than the second doping concentration of the p-type second epitaxial layer 206, such that the first resistivity of the p-type first epitaxial layer 204 is less than the second resistivity of the p-type second epitaxial layer 206. Thereafter, a hard mask layer 208 is formed on the p-type second epitaxial layer 206. Thereafter, photolithography and etch processes are carried out to pattern the hard mask layer 208 to expose the p-type second epitaxial layer 206. Thereafter, a plurality of through holes 206a are formed in the p-type second epitaxial layer 206, and the etch is continuously performed on the p-type first epitaxial layer 204 to form a plurality of trenches 204a in the p-type first epitaxial layer 204. Each trench 204a is right under each through hole 206a, such that each through hole 206a exposes each trench 204a. In this embodiment, the hard mask layer 208 may include silicon nitride or silicon dioxide, but be not limited thereto. In other embodiments according to the present invention, a p-type ion implantation process may be optionally carried out after formation of the p-type second epitaxial layer 206 to form a p-well within the p-type second epitaxial layer 206 to adjust the threshold voltage.

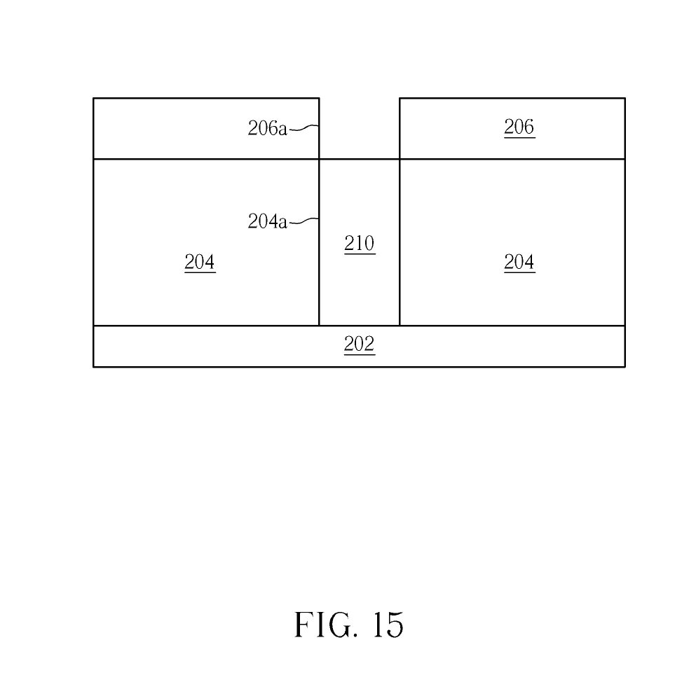

Thereafter, as shown in FIG. 15, a dopant source layer 210 is deposited to fill each through hole 206a and each trench 204a. The dopant source layer 210 includes a plurality of n-type dopants. Thereafter, an etch-back process is carried out to remove the dopant source layer 210 on the hard mask layer 208 and within each through hole 206a. Thereafter, the hard mask layer 208 is removed. In this embodiment, the dopant source layer 210 includes arsenic silicate glass (ASG) or phosphor silicate glass (PSG), but is not limited thereto. The dopant source layer 210 located within the through holes 206a may be not completely removed in the etch-back process for removing the dopant source layer 210; i.e., the upper surface of the remaining dopant source layer 210 and the upper surface of the p-type first epitaxial layer 204 may be placed at a same plane, or the upper surface of the remaining dopant source layer 210 may be between the lower surface of the p-type second epitaxial layer 206 and the upper surface of the p-type second epitaxial layer 206.

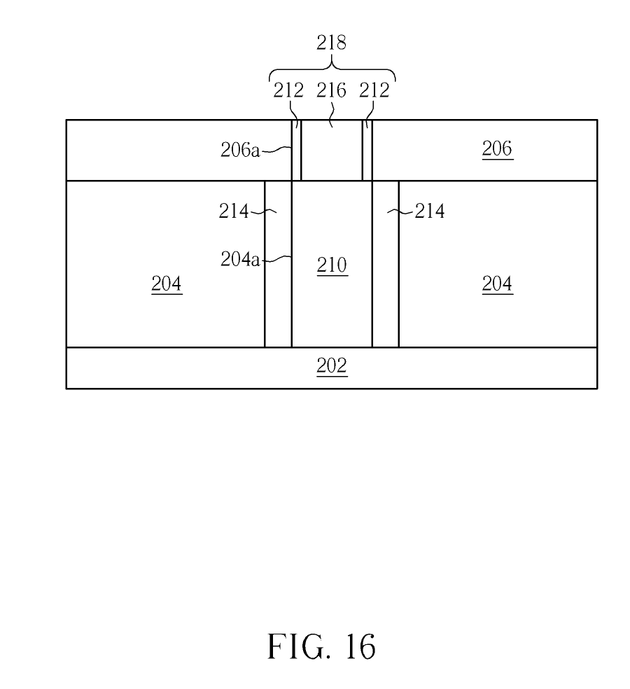

Thereafter, as shown in FIG. 16, a gate insulation layer 212 is formed on two sidewalls of each through hole 206a and on the p-type second epitaxial layer 206, and, at the same time, the n-type dopant in the dopant source layer 210 is allowed to diffuse into the p-type first epitaxial layer 204 to form two n-type doped diffusion regions 214 in the p-type first epitaxial layer 204 at two sides of each trench 204a for serving as drains of the power transistor device. Thereafter, a conductive layer is formed on the p-type second epitaxial layer 206 and in the through holes 206a. Thereafter, the portions of the gate insulation layer 212 and the conductive layer located on the p-type second epitaxial layer 206 are removed to form a gate conductive layer 216 in the through holes 206a, and the gate insulation layer 212 is between the p-type second epitaxial layer 206 and the gate conductive layer 216. The gate insulation layer 212 and the gate conductive layer 216 form a gate structure 218. The gate conductive layer 216 serves as a gate of the power transistor device in this embodiment, and the p-type second epitaxial layer 206 adjacent to the gate insulation layer 212 may serve as the channel region of the power transistor device in this embodiment. The gate conductive layer 216 in this embodiment may include polysilicon, but is not limited thereto. In other embodiments according to the present invention, the step of forming the gate insulation layer 212 and the step of forming the n-type doped diffusion regions 214 may be carried out separately. Furthermore, the dopant source layer 210 in the trenches 204a may be removed and an insulation layer may be formed in the trenches 204a between the step of forming the n-type doped diffusion regions 214 and the step of forming the gate conductive layer 216.

It should be noted that because the second doping concentration of the p-type second epitaxial layer 206 utilized as a channel region is less than the first doping concentration of the p-type first epitaxial layer 204, in comparison with utilization of the p-type first epitaxial layer 204 as the channel region, utilization of the p-type second epitaxial layer 206 having a less doping concentration as the channel region can effectively reduce the threshold voltage of the power transistor device.

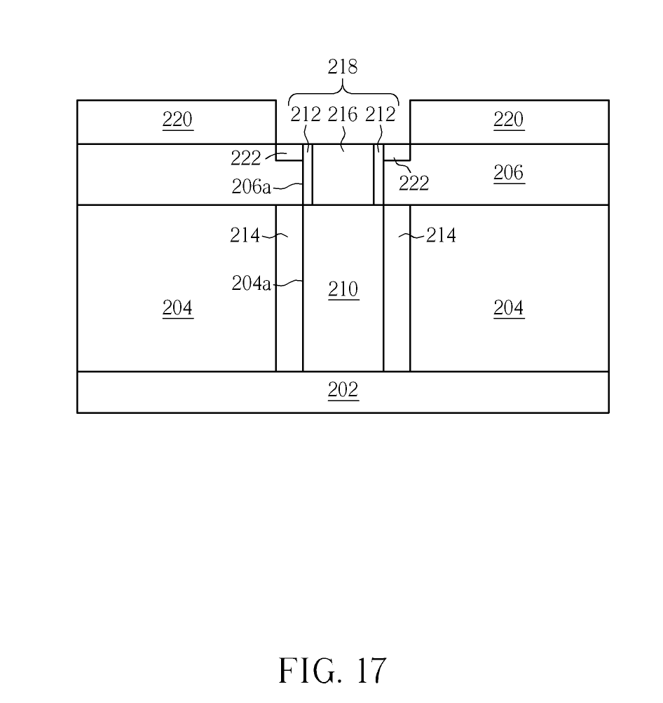

Thereafter, as shown in FIG. 17, a patterned photo resist layer 220 is formed on the p-type second epitaxial layer 206 to expose portions of the p-type second epitaxial layer 206 at two sides of each through hole 206a and the gate structure 218. Thereafter, an n-type ion implantation process is carried out to form two n-type doped source regions 222 in the p-type second epitaxial layer 206 at two sides of the through holes 206a, respectively, for serving as sources of the power transistor device in this embodiment. For this reason, the power transistor device according to this embodiment is a trench-type power transistor device.

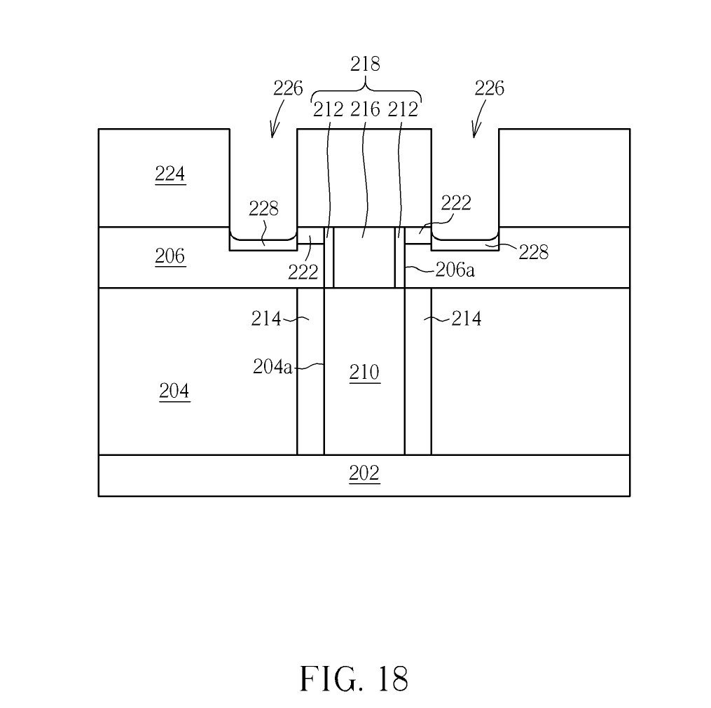

Thereafter, as shown in FIG. 18, the patterned photo resist layer 220 is removed and a dielectric layer 224 is formed to cover the p-type second epitaxial layer 206 and the gate structure 218. Thereafter, photolithography and etching processes are carried out to form at least one contact hole 226 in the dielectric layer 224 to expose the p-type second epitaxial layer 206 and the n-type doped source regions 222. Thereafter, a p-type ion implantation process is carried out to form at least one p-type doped contact region 228 in the p-type second epitaxial layer 206, and the p-type doped contact region 228 contacts the n-type doped source region 222.

Thereafter, as shown in FIG. 19, a source metal layer 230 is formed on the dielectric layer 224 and in the contact hole 226, and a drain metal layer is formed on the back of the n-type substrate 202. In this embodiment, the step of forming the source meta layer 230 may include performing a process such as a plasma sputtering deposition process or an electron beam deposition process. The source metal layer 230 may include metal or metal compound, such as titanium, titanium nitride, aluminum or tungsten, but is not limited thereto. A power transistor device 200 according to this embodiment is accordingly formed. In other embodiments according to the present invention, a contact plug may be formed in the contact hole 226 before the source metal layer 230 is formed, or a barrier layer may be formed on the p-type second epitaxial layer 206 of the bottom of the contact hole 226 in advance.

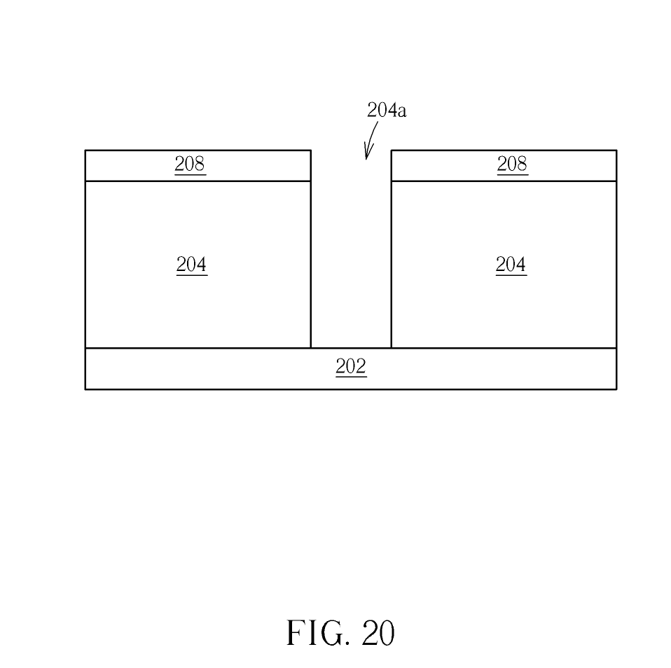

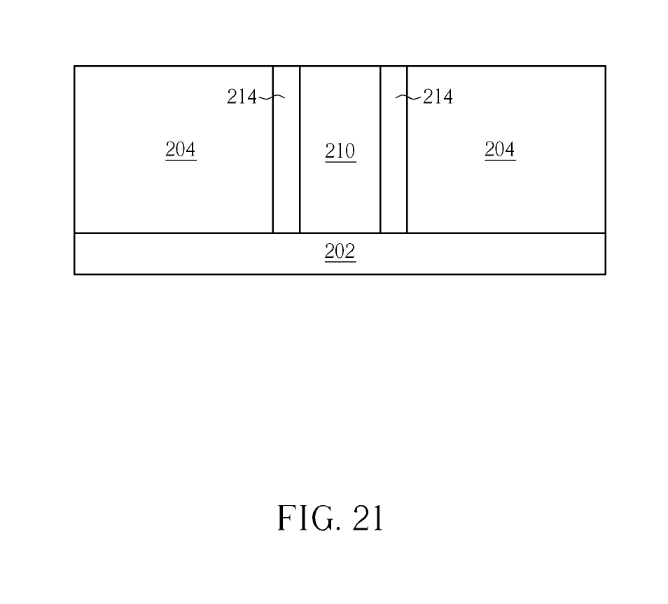

The method of fabricating a power transistor device according to the present invention is not limited to forming the p-type first epitaxial layer and the p-type second epitaxial layer in advance and then forming the n-type doped diffusion region, but the step of forming the n-type doped diffusion region may be carried out between the step of forming the p-type first epitaxial layer and the step of forming the p-type second epitaxial layer. Please refer to FIGS. 20 to 21 with FIGS. 15 to 19 together. FIGS. 20 to 21 are schematic cross-sectional views illustrating a method of fabricating a power transistor device according to the fourth preferred embodiment of the present invention. Some elements the same as those in the third embodiment may be denoted with the same referral numbers and some steps the same as those in the first embodiment may be not described redundantly for conciseness. As shown in FIG. 20, in comparison with the method according to the third embodiment, in this embodiment, the hard mask layer 208 is formed on the p-type first epitaxial layer 204 after the p-type first epitaxial layer 204 is formed. Thereafter, photolithography and etch processes are carried out to pattern the hard mask layer 208 to expose the p-type first epitaxial layer 204. Thereafter, at least one trench 204a is formed in the p-type first epitaxial layer 204. Thereafter, as shown in FIG. 21, the hard mask layer 208 is removed, and the trench 204a is filled with the dopant source layer 210. Thereafter, a thermal drive-in process is carried out to diffuse n-type dopants into the p-type first epitaxial layer 204 to form n-type doped diffusion regions 214 in the p-type first epitaxial layer 204 at two sides of the trench 204a. Thereafter, as shown in FIG. 15, a p-type second epitaxial layer 206 is formed on the p-type first epitaxial layer 204. Thereafter, photolithography and etch processes are carried out to pattern the p-type second epitaxial layer 206 to form a through hole 206a to expose the dopant source layer 210. As the step of forming the gate structure 218 and the following steps in this embodiment are the same as those described in the third embodiment, and the obtained power transistor device 200 also has a structure the same as shown in FIG. 19, they are not described redundantly for conciseness.

Summarized from the above description, in the present invention, the doping concentration of the second epitaxial layer on the first epitaxial layer is made to be less than the doping concentration of the first epitaxial layer, so that the concentration of dopant further required in the step of forming a doped base region in the second epitaxial layer can be reduced, and, in turn, the doping concentration of channel region of the power transistor device can be stably controlled. Thereby, the threshold voltage of the power transistor device can be reduced and effectively controlled. Furthermore, in the case that the first epitaxial layer is utilized to serve as the drift layer of the power transistor device, since the thickness of the first epitaxial layer is greater than the thickness of the second epitaxial layer and a super junction is formed, the voltage bearing ability as a whole and on-resistance of the device may be not significantly altered by the additional second epitaxial layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A power transistor device, comprising:
a substrate having a first conductive type;
a first epitaxial layer disposed on the substrate and having a second conductive type different from the first conductive type, wherein the first epitaxial layer has a first doping concentration;
a doped diffusion region disposed in the first epitaxial layer and having the first conductive type;
a second epitaxial layer disposed on the first epitaxial layer and the doped diffusion region, having the second conductive type, and having at least one through hole, wherein, the second epitaxial layer has a second doping concentration less than the first doping concentration;
a gate structure disposed in the through hole; and
a doped source region disposed in the second epitaxial layer at one side of the through hole and having the first conductive type.

2. The power transistor device according to claim 1, wherein, the first epitaxial layer has a first resistivity, the second epitaxial layer has a second resistivity, and the second resistivity is greater than the first resistivity.

3. The power transistor device according to claim 1, wherein the first epitaxial layer comprises a trench right under the through hole, and the doped diffusion region is in the first epitaxial layer at one side of the trench.

4. The power transistor device according to claim 3, further comprising a dopant source layer fully filling the trench.

5. The power transistor device according to claim 1, wherein, the gate structure comprises a gate conductive layer and a gate insulation layer, and the gate insulation layer is disposed between the gate conductive layer and the second epitaxial layer.

6. A method of fabricating a power transistor device, comprising:
providing a substrate having a first conductive type;
forming a first epitaxial layer having a second conductive type different from the first conductive type on the substrate, wherein the first epitaxial layer has a first resistivity;
forming a second epitaxial layer having the second conductive type on the first epitaxial layer, wherein, the second epitaxial layer comprises at least one through hole and has a second resistivity greater than the first resistivity;
forming a doped diffusion region having the first conductive type in the first epitaxial layer;
forming a gate structure in the through hole; and
forming a doped source region having the first conductive type in the second epitaxial layer at one side of the through hole.

7. The method of fabricating a power transistor device according to claim 6, wherein forming the doped diffusion region is performed after forming the second epitaxial layer.

8. The method of fabricating a power transistor device according to claim 7, wherein forming the doped diffusion region comprising:
forming a through hole in the second epitaxial layer and forming a trench in the first epitaxial layer, wherein the through hole exposes the trench;
filling the trench with a dopant source layer, the dopant source layer comprising a plurality of dopants having the first conductive type; and
performing a thermal drive-in process to diffuse the dopants into the first epitaxial layer to form the doped diffusion region.

9. The method of fabricating a power transistor device according to claim 8, wherein the dopant source layer comprises arsenic silicate glass or phosphor silicate glass.

10. The method of fabricating a power transistor device according to claim 6, wherein, forming the doped diffusion region is performed before forming the second epitaxial layer.

11. The method of fabricating a power transistor device according to claim 10, wherein forming the doped diffusion region comprises:
forming a trench in the first epitaxial layer;
filling the trench with a dopant source layer, the dopant source layer comprising a plurality of dopants having the first conductive type; and
performing a thermal drive-in process to diffuse the dopants into the first epitaxial layer to form the doped diffusion region.
